(19) United States
(12) Patent Application Publication
(10) Pub. No.: US 2019/0382619 A1
(43) Pub. Date: Dec. 19, 2019

(54) Tungsten Chemical Mechanical Polishing Compositions

(71) Applicant: Versum Materials US, LLC, Tempe, AZ (US)

(72) Inventors: Xiaobo Shi, Tempe, AZ (US); Chun Lu, Tempe, AZ (US); Mark Leonard O'Neill, Tempe, AZ (US)

(73) Assignee: Versum Materials US, LLC, Tempe, AZ (US)

(21) Appl. No.: 16/432,347

(22) Filed: Jun. 5, 2019

Related U.S. Application Data
(60) Provisional application No. 62/686,198, filed on Jun. 18, 2018.

(51) Int. Cl. C09G 1/02; H01L 21/306

(52) U.S. Cl. CPC C09G 1/02; H01L 21/30625

(57) ABSTRACT

Tungsten (W) chemical mechanical polishing (CMP) compositions and their related methods and systems are disclosed. The compositions comprise iron-ligand complexes or metal-ligand complexes as catalyst to induce the formation of hydroxyl radical to enhance oxidation rates of W film and provide high and tunable W film removal rates. The W chemical mechanical polishing (CMP) compositions can be used in wide pH range, therefore, provide highly tunable W: oxide or barrier layer selectivity. The compositions afford low dishing and low erosion levels.

### CROSS REFERENCE TO RELATED PATENT APPLICATIONS

The present patent application claims the benefit of U.S. Provisional Patent Application Ser. No. 62/686,198 filed Jun. 18, 2018.

### BACKGROUND OF THE INVENTION

This invention relates generally to the chemical-mechanical planarization (CMP) of tungsten-containing substrates on semiconductor wafers, the slurry compositions, methods and systems therefor. More specifically, the slurry compositions comprise Ferric-Ligand or Metal-Ligand Complexes as Catalyst.

This invention is especially useful for tungsten bulk CMP applications where low dishing/plug recess and low array erosion on planarized substrates is desired and/or required.

Chemical mechanical planarization (chemical mechanical polishing, CMP) for planarization of semiconductor substrates is now widely known to those skilled in the art and has been described in numerous patents and open literature publications. An introductory reference on CMP is as follows: “Chemical-Mechanical Polish” by G. B. Shinn et al., Chapter 15, pages 415-460, in Handbook of Semiconductor Manufacturing Technology, editors: Y. Nishi and R. Doering, Marcel Dekker, New York City (2000).

In a typical CMP process a substrate (e.g., a wafer) is placed in contact with a rotating polishing pad attached to a platen. A CMP slurry (or composition), typically an abrasive and chemically reactive mixture, is supplied to the pad during CMP processing of the substrate. During the CMP process, the pad (fixed to the platen) and substrate are rotated while a wafer carrier system or polishing head applies pressure (downward force) against the substrate. The slurry accomplishes the planarization (polishing) process by chemically and mechanically interacting with the substrate film being planarized because of the rotational movement of the pad parallel to the substrate. Polishing is continued in this manner until the desired film on the substrate is removed with the usual objective being to effectively planarize the substrate. Typically, metal CMP slurries contain an abrasive material, such as silica or alumina, suspended in an oxidizing, aqueous medium.

There are large numbers of materials used in the manufacture of integrated circuits such as a semiconductor wafer. The materials generally fall into three categories—dielectric material, adhesion and/or barrier layers, and conductive layers. The use of the various substrates, e.g., dielectric material such as tetraethylorthosilicate (TEOS), plasma enhanced tetraethylorthosilicate (PETEOS), and low-k dielectric materials; barrier/adhesion layers such as tantalum, titanium, tantalum nitride, and titanium nitride; and conductive layers such as copper, aluminum, tungsten, and noble metals are known in the industry.

Integrated circuits are interconnected using well-known multilevel interconnections. Interconnection structures normally have a first layer of metallization, an interconnection layer, a second level of metallization, and typically third and subsequent levels of metallization. Interlevel dielectric materials such as silicon dioxide and sometimes low-k materials are used to electrically isolate the different levels of metallization in a silicon substrate or well. The electrical connections between different interconnection levels are made using metallized vias and tungsten vias. U.S. Pat. No. 4,789,648 describes a method for preparing multiple metallized layers and metallized vias in insulator films. In a similar manner, metal contacts are used to form electrical connections between interconnection levels and devices formed in a well. The metal vias and contacts are generally filled with tungsten and generally employ an adhesion layer such as titanium nitride (TiN) and/or titanium to adhere a metal layer such as a tungsten metal layer to the dielectric material.

In one semiconductor manufacturing process, metallized vias or contacts are formed by a blanket tungsten deposition followed by a CMP step. In a typical process, via holes are etched through the interlevel dielectric (ILD) to interconnection lines or to a semiconductor substrate. Next, a thin adhesion layer such as titanium nitride and/or titanium is generally formed over the ILD and is directed into the etched via hole. Then, a tungsten film is blanket deposited over the adhesion layer and into the via. The deposition is continued until the via hole is filled with tungsten. Finally, the excess tungsten is removed by chemical mechanical polishing (CMP) to form metal vias.

The ratio of the removal rate of a metal (e.g., tungsten) to the removal rate of a dielectric base is called the “selectivity” for removal of the metal in relation to removal of the dielectric during CMP processing of substrates comprised of metal and dielectric material.

When CMP slurries with high selectivity for removal of metal in relation to dielectric are used, the metal layers are easily over-polished creating a depression or “dishing” effect in the metalized areas. This feature distortion is unacceptable due to lithographic and other constraints in semiconductor manufacturing.

Another feature distortion that is unsuitable for semiconductor manufacturing is called “erosion.” Erosion is the topography difference between a field of dielectric and a dense array of metal vias or trenches. In CMP, the materials in the dense array may be removed or eroded at a faster rate than the surrounding field of dielectric. This causes a topography difference between the field of dielectric and the dense metal (e.g., copper or tungsten) array.

As industry standards trend toward smaller device features, there is an ever-developing need for CMP slurries that deliver superior planarization of the nanostructures of IC chips. Specifically, for 45 nm technology nodes and smaller feature sizes, slurry products must deliver low removal rate selectivity between metal and dielectric, thereby lowering erosion while maintaining sufficient removal rate and low defect levels. Furthermore, in the competitive market of CMP consumables, low cost of ownership, specifically through concentration of CMP slurry, is quickly becoming an industry standard.

A typically used CMP slurry has two actions, a chemical component and a mechanical component. An important consideration in slurry selection is “passive etch rate.” The passive etch rate is the rate at which a metal (e.g., copper) is dissolved by the chemical component alone and should be significantly lower than the removal rate when both the chemical component and the mechanical component are involved. A large passive etch rate leads to dishing of the metallic trenches and vias, and thus, preferably, the passive etch rate is less than 10 nanometers per minute.

These are three general types of layers that can be polished. The first layer is interlayer dielectrics (ILD), such as silicon oxide and silicon nitride. The second layer is metal layers such as tungsten, copper, aluminum, etc., which are used to connect the active devices. This application addresses polishing the metal layer, particularly tungsten. The third type of layer is an adhesion/barrier layer such as titanium nitride.

In the case of CMP of metals, the chemical action is generally considered to take one of two forms. In the first mechanism, the chemicals in the solution react with the metal layer to continuously form an oxide layer on the surface of the metal. This generally requires the addition of an oxidizer to the solution such as hydrogen peroxide, ferric nitrate, etc. Then the mechanical abrasive action of the particles continuously and simultaneously removes this oxide layer which is formed on the metal layer. A judicious balance of these two processes obtains optimum results in terms of removal rate and polished surface quality.

In the second mechanism, no protective oxide layer is formed. Instead, the constituents in the solution chemically attack and dissolve the metal, while the mechanical action is largely one of mechanically enhancing the dissolution rate by such processes as continuously exposing more surface area to chemical attack, raising the local temperature (which increases the dissolution rate) by the friction between the particles and the metal and enhancing the diffusion of reactants and products to and away from the surface by mixing and by reducing the thickness of the boundary layer.

W CMP bulk polish process is a key W CMP step in W CMP. Therefore, W CMP polishing compositions need to be well designed, and can afford desirable W bulk film removal rates and selectivity towards barrier and dielectric films, such as TiN and TEOS films. After removal of overburden W layers through W bulk CMP process, the W patterned wafers will be further polished for achieving improved planarity across the whole patterned wafers and improving W plug recess or W trench dishing, thus, increasing the fabrication yield of integrated electronic chips.

The slurry composition is an important factor in the CMP step. Depending on the choice of the oxidizing agent, the abrasive, and other useful additives, the polishing slurry can be tailored to provide effective polishing of metal layers at desired polishing rates while minimizing surface imperfections, defects, corrosion, and erosion of oxide in areas with tungsten vias. Furthermore, the polishing slurry may be used to provide controlled polishing selectivity to other thin-film materials used in current integrated circuit technology such as titanium, titanium nitride and the like.

In general, in W CMP polishing compositions, the use of iron-containing catalyst is a key component which will enhance the W film surface oxidation by generating more powerful oxidizing species, hydroxyl radical during a W bulk CMP polishing process.

However the water-soluble iron inorganic salts, such as ferric nitrate, ferric sulfate or ferric phosphate, when used as catalysts at neutral pH conditions or at pH≥5.5 conditions, induced the colloidal silica abrasive particle precipitations, thus, such water-soluble iron inorganic salts cannot be used as catalysts in W CMP slurries under pH conditions mentioned above.

U.S. Pat. No. 5,958,288 described a chemical mechanical polishing composition comprising an oxidizing agent and at least one catalyst having multiple oxidation states, the composition being useful when combined with an abrasive or with an abrasive pad to remove metal layers from a substrate.

U.S. Pat. No. 9,567,491 described a chemical-mechanical polishing composition includes colloidal silica abrasive particles having a chemical compound incorporated therein. The chemical compound may include a nitrogen-containing compound such as an aminosilane or a phosphorus-containing compound. Methods for employing such compositions include applying the composition to a semiconductor substrate to remove at least a portion of a layer.

U.S. Pat. No. 9,303,189B2 described a chemical mechanical polishing composition for polishing a substrate having a tungsten layer includes a water based liquid carrier, a colloidal silica abrasive dispersed in the liquid carrier and having a permanent positive charge of at least 6 mV, an amine containing polymer in solution in the liquid carrier, and an iron containing accelerator. A method for chemical mechanical polishing a substrate including a tungsten layer includes contacting the substrate with the above described polishing composition, moving the polishing composition relative to the substrate, and abrading the substrate to remove a portion of the tungsten from the substrate and thereby polish the substrate.

U.S. Pat. No. 7,371,679B2 described a method of forming a metal line in a semiconductor device including forming an inter-metal dielectric (IMD) layer on the semiconductor substrate including the predetermined pattern, planarizing the IMD layer through a first CMP process, and patterning a via hole on the planarized substrate. The method further includes depositing a barrier metal layer in the via hole, filling a refractory metal in an upper part of the barrier metal layer, planarizing the substrate filled with the refractory metal by performing a second CMP process, forming a refractory metal oxide layer by oxidizing a residual refractory metal region created by the second CMP process, and forming a refractory metal plug by removing the refractory metal oxide layer through a third CMP process.

There is a significant need for tungsten CMP process and slurry(s) which includes W CMP bulk polishing slurries that afford low dishing and plug recess effects especially since the semiconductor industry continues to move towards smaller and smaller feature sizes.

### BRIEF SUMMARY OF THE INVENTION

The present invention provides a solution to this significant need.

In one aspect, W CMP polishing compositions are provided for CMP of a substrate comprising tungsten, dielectric films such as oxide films, and barrier films such as TiN or Ti, TaN or Ta. The W CMP polishing composition comprises:
abrasive;
metal-ligand complex catalyst;
oxidizing agent; and
solvent selected from the group consisting of water, liquid which is miscible with water, and combinations thereof;
optionally,
corrosion inhibitor for W;
pH adjusting agent;
biocide; and
stabilizer;
wherein pH of the CMP composition ranges are from 2.0 to 10.0, preferably 3 to 9.5, more preferably 4 to 9 and the CMP composition is a stable composition.

The suitable abrasive include but are not limited to alumina, ceria, germania, colloidal silica, high purity colloidal silica having <1 ppm trace metal, titania, zirconia, a metal-modified or composite particles abrasive, such as iron-coated silica, silica-coated alumina, and combinations thereof. Colloidal silica and high purity colloidal silica particles are preferred.

The abrasive particles have a mean particle size ranging from 20 nm to 180 nm; 30 nm to 150 nm, 35 to 80 nm, or 40 to 75 nm.

The concentrations of abrasive range from 0.1 wt. % to 20 wt. %, preferably from 0.1 wt. % to 10 wt. %, more preferably from 0.1 wt. % to 5 wt. %, and most preferably from 0.1 wt. % to 3 wt. %; which are selected for tuning film removal rates, especially tuning dielectric film removal rates

The metal-ligand complexes have the general molecular structures depicted as below:

M(n+)−Lm

wherein, n+ indicates the oxidation number of metal ions in metal-ligand complexes and is 1+, 2+, or 3+ or other positive charges; m refers to the numbers of the ligand molecules directly and chemical bonded to the cationic iron center in metal-ligand complexes. The numbers of m can be 1, 2, 3, 4, 5, or 6 respectively which depend on the selected ligands in forming metal-ligand complexes. The metal ions in metal-ligand complexes include, but not limited to Fe, Cs, Ce, Ru, Os, Co, Rh, Ir, Ni, Pd, Pt, Cu, Ag, Au ions and other metal ions.

The ligand molecules used in forming metal-ligand complexes include, but not limited to, the organic amines, organic acids with mono-, bi-, tri-, tetra- or more carboxylic, sulfonic or phosphoric acid functional groups, organic acid salts (ammonium salts, potassium salts or sodium salts) with mono-, bi-, tri-, tetra- or more carbonate or sulfonate or phosphate functional groups, pyridine molecule and its derivatives, bipyridine molecule and its derivatives, terpyridine and its derivatives, organic aromatic acids and their salts, picolinic acid and its derivatives.

The used ligand compounds in metal-ligand complex are bonded to metal ion center through chemical bonding which allow the use of such metal-ligand complex as catalyst in W CMP polishing compositions in wide pH ranges.

The metal-ligand complex is used as catalyst with the concentrations ranging from 5 ppm to 10000 ppm, the preferred concentrations ranges from 10 ppm to 3000 ppm, the more preferred concentrations ranges from 50 ppm to 500 ppm by weight.

The iron-ligand complexes are preferred.

The iron-ligand complex catalysts have the following general molecular structures:

Fe(n+)−Lm

wherein, n+ indicates the oxidation number of iron in iron-ligand complexes, n+ can be 2+ or 3+ or other positive charges, m refers to the numbers of the ligand molecules directly and chemical bonded to the cationic iron center in iron-ligand complexes. The numbers of m can be 1, 2, 3, 4, 5, or 6 respectively which depend on the selected ligands in forming iron-ligand complexes.

Examples of iron-ligand complexes which are used as catalyst in the invented W CMP polishing compositions herein are listed below:

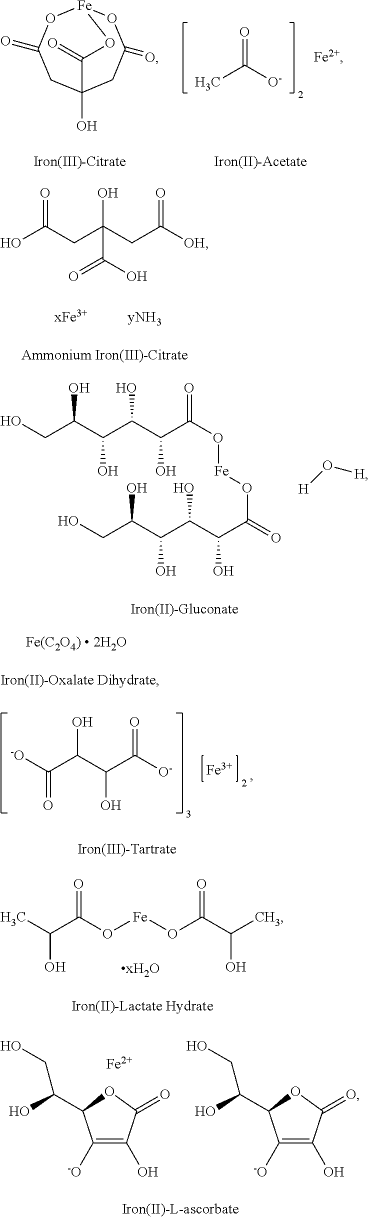

and combinations thereof.

Suitable oxidizing agents include, but are not limited to per-oxy oxidizer comprising at least one peroxy group (—O—O—); peroxides (e.g., hydrogen peroxide H₂O₂ and urea hydrogen peroxide); persulfates (e.g., monopersulfates and dipersulfates); sodium or potassium peroxide; benzyl peroxide; di-t-butyl peroxide; percarbonates, perchlorates, perbromates, periodates, and acids thereof; peroxyacids (e.g., peracetic acid, perbenzoic acid, m-chloroperbenzoic acid, salts thereof); iodic acid and salts thereof; nitric acid; and combinations thereof; and the oxidizing agent ranges from 1 ppm and 100000 ppm.

Preferred oxidizing agents include hydrogen peroxide, urea-hydrogen peroxide, sodium or potassium peroxide, benzyl peroxide, di-t-butyl peroxide, peracetic acid, monopersulfuric acid, dipersulfuric acid, iodic acid, and salts thereof, and mixtures thereof. Hydrogen peroxide (H₂O₂) or periodic acid is a preferred oxidizing agent. In an embodiment, the oxidizing agent is hydrogen peroxide. Strong acid oxidizers, such as nitric acid, can also be used.

The per-oxy oxidizer or strong acid oxidizer is typically present in an amount between 1 ppm and 100000 ppm, preferably between 100 ppm to 50000 ppm, and more preferably between 5000 ppm to 35000 ppm by weight

An oligomer or polymer comprising of ethyleneimine, propyleneimine, polyethyleneimine(PEI) or combinations, is used as W corrosion inhibitor. The W corrosion inhibitor has, for example, of molecular weight from about 500 to over 1000000, more typically between 500 and 15000.

The polyethyleneimine (PEI) can be either branched or linear, and the branched polyethyleneimines is preferably at least half of the polyethyleneimines are branched and contains primary, secondary and tertiary amino groups; and the linear polyethyleneimines contain all secondary amines.

The branched polyethyleneimine can be represented by the formula (—NHCH₂CH₂-)ₓ[—N(CH₂CH₂NH₂)CH₂CH₂-]_{y} shown below:

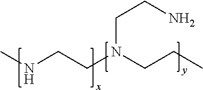

wherein x can be 2 to >40; and y can be 2 to >40, preferably each of x and y are independently 11 to 40, alternately, each of x and y are independently 6 to 10, further alternatively x and y are independently 2-5.

The corrosion inhibitor for W ranging between 0.01 to 1000 ppm, preferably between 0.1 to 100 ppm, and more preferably between 0.5 to 10 ppm by weight; and most preferably between 1 to 5 ppm by weight;

Inorganic acids, such as nitric acid, sulfonic acid, or phosphoric acid is used as pH adjusting agent, and inorganic base, such as ammonia hydroxide, potassium hydroxide or sodium hydroxide is also used as pH adjust agent.

Suitable biocides include but are not limited to Kathon™, Kathon™ CG/ICP II, from Dow Chemical Co. They have active ingredients of 5-chloro-2-methyl-4-isothiazolin-3-one and 2-methyl-4-isothiazolin-3-one.

Biocides are used in a range from 0.0001 wt. % to 0.05 wt. %; preferably from 0.0005 wt. % to 0.025 wt. %, and more preferably from 0.001 wt. % to 0.01 wt. %.

Stabilizers may also be used. At low pH, Stabilizers are optional. Stabilizers include but are not limited to organic carboxylic acids or organic carboxylic acid salts. These stabilizers include, but not limited to, citric acid, tartaric acid, lactic acid, oxalic acid, ascorbic acid, acetic acid, gluconic acid, and their sodium salts, potassium salts and ammonium salts.

Stabilizers can be used in the range of 250 ppm to 10000 ppm, and more preferred range of 400 ppm to 5000 ppm (or 0.04 wt. % to 0.5 wt. %).

In another embodiment, the invention is a method of chemical mechanical polishing of a substrate comprising tungsten, said method comprising: movably contacting a surface of the substrate with a) an abrasive, and b) a liquid component comprising: water; an acid, preferably a mineral acid or base, sufficient to provide a pH of 2 to 10, for example between 2.5 and 10.0; a per-oxy oxidizer ranges between 1 ppm and 100000 ppm, preferably between 100 ppm to 50000 ppm, and more preferably between 5000 ppm to 35000 ppm by weight; a catalyst of an iron-ligand compound which reacts at elevated temperature with the per-oxy oxidizer to generate hydroxyl radicals and synergistically increase tungsten removal rates; and between 0.1 and 10 ppm by weight of a polyethyleneimine, wherein in a preferred embodiment the liquid component is deionized wafer, and wherein the polishing removes greater than 2,000 angstroms per minute (“A/min”) of tungsten at 3 psi downforce and remove varied thickness of oxide film. The total iron-ligand complex as catalyst in the slurry is typically from 50 ppm to 500 ppm by weight, based on the total weight of the slurry.

In another aspect, the invention is a method of chemical mechanical polishing of a substrate comprising tungsten; dielectric layer such as oxide; and barrier films, such as TiN or Ti or TaN or Ta.

The method of chemical mechanical polishing a semiconductor substrate containing a surface comprising tungsten and at least one of dielectric layer or barrier layer, comprising steps of:
providing the semiconductor substrate;
providing a polishing pad;
providing the chemical mechanical polishing (CMP) compositions disclosed above contacting the surface of the semiconductor substrate with the polishing pad and the chemical mechanical polishing composition; and
polishing the surface of the semiconductor;
wherein
the dielectric layer is an oxide film and the barrier layer is selected from the group consisting of TiN, Ti, TaN, Ta and combinations thereof.

The removal selectivity of W vs the at least one dielectric layer or barrier layer is between 4:1 and 50:1.

The removal rate for tungsten is greater than 1300, 1500, 2000 Å/min, or 2500 Å/min; removal rate for the dielectric layer is between 15 to 200 Å/min; removal rate for the barrier layer is between 30 to 500 Å/min.

In one embodiment, the method comprises movably contacting a surface having tungsten thereon with a) an abrasive suspended in a liquid to form a slurry, said slurry comprising: between 0.1 and 20% by weight, for example between 0.5 and 5% by weight of said abrasive; said liquid comprising water; an acid or a base sufficient to provide a pH of 2 to 10; of a per-oxy oxidizer ranges from 1 ppm and 100000 ppm, preferably between 100 ppm to 50000 ppm, and more preferably between 5000 ppm to 35000 ppm by weight; and between 0.01 to 1000 ppm, preferably between 0.1 to 100 ppm, and more preferably between 0.5 to 10 ppm by weight; and most preferably between 1 to 5 ppm by weight of a polyethyleneimine; said liquid being substantially free of fluoride-containing compounds, wherein the polishing removes greater than 2000 angstroms per minute (Å/min) of tungsten and varied thickness of oxide films.

In another embodiment, the method comprises movably contacting a surface having tungsten thereon with a) an abrasive comprising silica, and b) a liquid component comprising water, an acid sufficient to provide a pH of 2 to 10, a per-oxy oxidizer, and between 0.1 and 10 ppm by weight of a polyethyleneimine, and between 0.1 and 4 ppm by weight of polyethyleneimine, wherein the polishing removes greater than 2000 angstroms per minute of tungsten and varied thickness of oxide films.

In yet another embodiment, the method comprises: movably contacting a surface of the substrate with a) an abrasive, and b) a liquid component comprising water, an acid sufficient to provide a pH of 2 to 10, a per-oxy oxidizer, between 50 ppm and 250 ppm by weight of an iron-ligand complex which reacts at elevated temperature induces the formation of hydroxyl radicals from with the per-oxy oxidizer to enhance W film oxidation reaction rate and tune tungsten removal rates, and between 0.1 and 10 ppm by weight of a polyethyleneimine.

Use of greater amounts of polyethyleneimine results in reduced tungsten removal rates while there is added static etch corrosion protection.

In yet another aspect, the invention is a system of chemical mechanical polishing of a substrate containing a surface comprising tungsten and at least one of dielectric layer such as oxide; and barrier films, such as TiN or Ti or TaN or Ta.

The system comprising:
the semiconductor substrate;
a polishing pad;
the chemical mechanical polishing (CMP) compositions disclosed above;
wherein the surface of the semiconductor substrate is in contact with the polishing pad and the chemical mechanical polishing composition.

In each of the above embodiments, the term “ppm” means parts per million by weight of the slurry (liquid plus abrasive), or of the liquid component if there is no abrasive suspended in the liquid.

And in a preferred embodiment the polishing composition is free of fluoride-containing compounds.

### BRIEF DESCRIPTION OF SEVERAL VIEWS OF THE DRAWINGS

In the accompanying drawing forming a material part of this description, there is shown:

FIG. 1 depicts the effect of film Removal Rates using W CMP Polish Composition in Working Example 1.

FIG. 2 depicts the effect of W Line Dishing using W CMP Polish Composition in Working Example 1.

FIG. 3 depicts the effect of Erosion using W CMP Polish Composition in Working Example 1.

FIG. 4 depicts the effect of Film Removal Rates using W CMP Polish Composition in Working of Example 2.

FIG. 5 depicts the effect of W Line Dishing using W CMP Polish Composition in Working Example 2.

FIG. 6 depicts the effect of Erosion using W CMP Polish Composition in Working Example 2.

FIG. 7 depicts the effect of Film Removal Rates using W CMP Polish Composition in Working of Example 3.

FIG. 8 depicts the effect of W Line Dishing using W CMP Polish Composition in Working Example 3.

FIG. 9 depicts the effect of Erosion using W CMP Polish Composition in Working Example 3.

FIG. 10 depicts the effect of Film Removal Rates (Å/min.) using W Polishing Compositions in Working Example 4.

FIG. 11 depicts the effects on W Line Dishing (Å) using W Polishing Compositions in Working Example 4.

### DETAILED DESCRIPTION OF THE INVENTION

This invention involves is on the W CMP bulk polishing compositions and systems used for chemical mechanical polishing of a substrate comprising tungsten, oxide (such as TEOS, PETEOS), and barrier films such as TiN or Ti or TaN or Ta.

The W CMP polishing composition comprises:
abrasive;
metal-ligand complex catalyst;
oxidizing agent; and
solvent selected from the group consisting of water, liquid which is miscible with water, and combinations thereof;
optionally,
corrosion inhibitor for W;
pH adjusting agent;
biocide; and
stabilizer;
wherein pH of the CMP composition ranges are from 2.0 to 10.0, preferably 3 to 9.5, more preferably 4 to 9.

The abrasive includes but is not limited to alumina, ceria, germania, colloidal silica silica, high purity colloidal silica having trace metal level <1 ppm, titania, zirconia, a metal-modified or composite particles abrasive, such as iron-coated silica, silica-coated alumina, and combinations thereof.

Colloidal silica and high purity colloidal silica particles are preferred.

The abrasive particles have any shape, such as spherical or cocoon shapes.

The high purity colloidal silica (due to the high purity) are prepared from TEOS or TMOS, such high purity colloidal silica particles have very low trace metal levels, typically in the ppb levels or very low ppm level, such as <1 ppm).

Abrasive particle shapes are measured by TEM or SEM methods. The mean abrasive sizes or particle size distribution can be measured by using any suitable techniques, such as disk centrifuge (DC) method, or dynamic light scattering (DLS), colloidal dynamic method, or by Malvern Size Analyzer.

The abrasive particles have a mean particle size ranging from 20 nm to 180 nm; 30 nm to 150 nm, 35 to 80 nm, or 40 to 75 nm.

The CMP composition can use two or more different abrasives having different sizes.

The concentrations of abrasive range from 0.1 wt. % to 20 wt. %, preferably from 0.1 wt. % to 10 wt. %, more preferably from 0.1 wt. % to 5 wt. %, and most preferably from 0.1 wt. % to 3 wt. %; which are selected for tuning film removal rates, especially tuning dielectric film removal rates.

The metal-ligand complexes have the general molecular structures depicted as below:

M(n+)−Lm

wherein, n+ indicates the oxidation number of metal ions in metal-ligand complexes and is 1+, 2+, or 3+ or other positive charges; m refers to the numbers of the ligand molecules directly and chemical bonded to the cationic iron center in metal-ligand complexes. The numbers of m can be 1, 2, 3, 4, 5, or 6 respectively which depend on the selected ligands in forming metal-ligand complexes. The metal ions in metal-ligand complexes include, but not limited to Fe, Cs, Ce, Ru, Os, Co, Rh, Ir, Ni, Pd, Pt, Cu, Ag, Au ions and other metal ions.

The ligand molecules used in forming metal-ligand complexes include, but not limited to, the organic amines, organic acids with mono-, bi-, tri-, tetra- or more carboxylic, sulfonic or phosphoric acid functional groups, organic acid salts (ammonium salts, potassium salts or sodium salts) with mono-, bi-, tri-, tetra- or more carbonate or sulfonate or phosphate functional groups, pyridine molecule and its derivatives, bipyridine molecule and its derivatives, terpyridine and its derivatives, organic aromatic acids and their salts, picolinic acid and its derivatives.

The used ligand compounds in metal-ligand complex are bonded to metal ion center through chemical bonding which allow the use of such metal-ligand complex as catalyst in W CMP polishing compositions in wide pH ranges.

The metal-ligand complex is used as catalyst with the concentrations ranging from 5 ppm to 10000 ppm, the preferred concentrations ranges from 10 ppm to 3000 ppm, the more preferred concentrations ranges from 50 ppm to 500 ppm by weight.

The iron-ligand complexes are preferred.

The iron-ligand complex catalysts have the following general molecular structures:

Fe(n+)−Lm

wherein, n+ indicates the oxidation number of iron in iron-ligand complexes, n+ can be 2+ or 3+ or other positive charges, m refers to the numbers of the ligand molecules directly and chemical bonded to the cationic iron center in iron-ligand complexes. The numbers of m can be 1, 2, 3, 4, 5, or 6 respectively which depend on the selected ligands in forming iron-ligand complexes.

Examples of iron-ligand complexes which are used as catalyst in the invented W CMP polishing compositions herein are listed below:

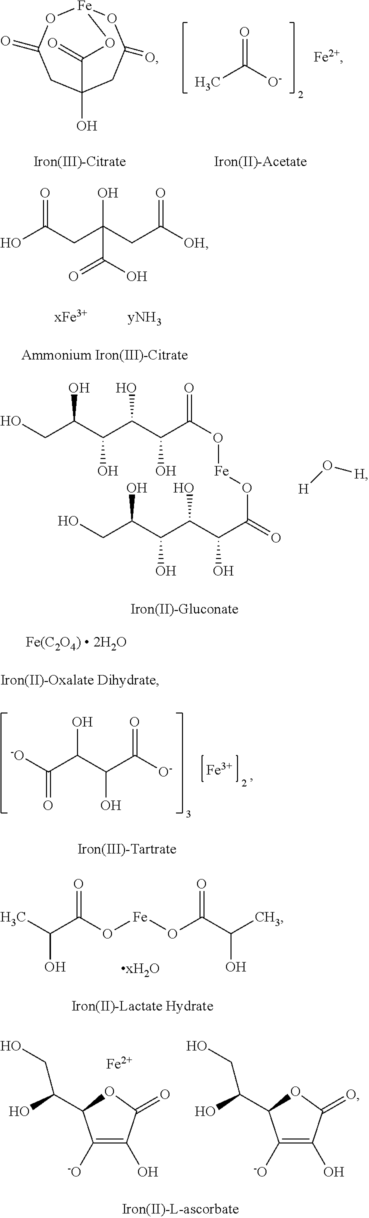

and combinations thereof.

The water-soluble metal-ligand complexes can be used as catalysts in W CMP polishing compositions not only at acidic pH conditions, but also at neutral pH or alkaline pH conditions.

But the water-soluble metal inorganic salts, such as ferric nitrate, ferric sulfate or ferric phosphate; cannot be used as catalysts in W CMP slurries at neutral pH condition, or at pH≥5.5 due to the colloidal silica abrasive particle precipitations.

Suitable oxidizing agents include, but are not limited to per-oxy oxidizer comprising at least one peroxy group (—O—O—); peroxides (e.g., hydrogen peroxide H₂O₂ and urea hydrogen peroxide); persulfates (e.g., monopersulfates and dipersulfates); sodium or potassium peroxide; benzyl peroxide; di-t-butyl peroxide; percarbonates, perchlorates, perbromates, periodates, and acids thereof; peroxyacids (e.g., peracetic acid, perbenzoic acid, m-chloroperbenzoic acid, salts thereof); iodic acid and salts thereof; nitric acid; and combinations thereof; and the oxidizing agent ranges from 1 ppm and 100000 ppm.

Preferred oxidizing agents include hydrogen peroxide, urea-hydrogen peroxide, sodium or potassium peroxide, benzyl peroxide, di-t-butyl peroxide, peracetic acid, monopersulfuric acid, dipersulfuric acid, iodic acid, and salts thereof, and mixtures thereof. Hydrogen peroxide (H₂O₂) or periodic acid is a preferred oxidizing agent. In an embodiment, the oxidizing agent is hydrogen peroxide. Strong acid oxidizers, such as nitric acid, can also be used.

The per-oxy oxidizer or strong acid oxidizer is typically present in an amount between 1 ppm and 100000 ppm, preferably between 100 ppm to 50000 ppm, and more preferably between 5000 ppm to 35000 ppm by weight.

An oligomer or polymer comprising of ethyleneimine, propyleneimine, polyethyleneimine(PEI) or combinations, is used as W corrosion inhibitor. The W corrosion inhibitor has, for example, of molecular weight from about 500 to over 1000000, more typically between 500 and 15000.

The polyethyleneimine (PEI) can be either branched or linear, and the branched polyethyleneimines is preferably at least half of the polyethyleneimines are branched and contains primary, secondary and tertiary amino groups; and the linear polyethyleneimines contain all secondary amines.

The branched polyethyleneimine can be represented by the formula (—NHCH₂CH₂-)ₓ[—N(CH₂CH₂NH₂)CH₂CH₂-]_{y} shown below:

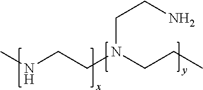

wherein x can be 2 to >40; and y can be 2 to >40, preferably each of x and y are independently 11 to 40, alternately, each of x and y are independently 6 to 10, further alternatively x and y are independently 2-5.

One problem with aggressive tungsten slurries is that the chemistry can attack tungsten during for example idle periods when there is no polishing, that is, no movement of abrasives sufficient to remove the oxide coating formed by the oxidizing system. In the absence of PEI, static etch for iron catalyzed peroxide systems can be as high as 200 to 300 Å/min. As little as 3 ppm PEI can reduce static etch to below 25 Å/min for iron-ligand complex catalyzed systems. Surprisingly very low levels of PEI are effective in the slurry.

The corrosion inhibitor for W ranging between 0.01 to 1000 ppm, preferably between 0.1 to 100 ppm, and more preferably between 0.5 to 10 ppm by weight; and most preferably between 1 to 5 ppm by weight.

At such concentrations, there is no foaming issues while using PEI as W corrosion inhibitors.

Inorganic acids, such as nitric acid, sulfonic acid, or phosphoric acid is used as pH adjusting agent, and inorganic base, such as ammonia hydroxide, potassium hydroxide or sodium hydroxide is also used as pH adjust agent.

The choice of acid or base is not limited provided that the strength of the acid or base is sufficient to afford a desired pH in the range of 2-10 for the slurry.

Suitable biocides include but are not limited to Kathon™, Kathon™ CG/ICP II, from Dow Chemical Co. They have active ingredients of 5-chloro-2-methyl-4-isothiazolin-3-one and 2-methyl-4-isothiazolin-3-one.

Biocides are used in a range from 0.0001 wt. % to 0.05 wt. %; preferably from 0.0005 wt. % to 0.025 wt. %, and more preferably from 0.001 wt. % to 0.01 wt. %.

This invention provides methods that utilizes the disclosed CMP compositions for chemical mechanical planarization of a tungsten-containing substrate. Minimization or prevention of dishing/erosion and plug recess of features on semiconductor substrates as well as tunability of selectivity during CMP processing is becoming increasingly more important as the semiconductor industry trends to smaller and smaller feature sizes in the manufacture of integrated circuits.

In an embodiment, the oxidizing agent is one (e.g., hydrogen peroxide) that can form free radicals in the presence of iron-ligand complex or copper-ligand compound or other metal-ligand complex present in the polishing composition that results in increased tungsten removal rates.

In another embodiment, an iron-ligand complex, such as iron-gluconate complex or iron(III)-oxalate is present as a component. This component serves as catalyst to induce free radical formation from a per-oxy oxidizer to increase the removal rate of tungsten (or other metals).

In yet another embodiment, the slurry can be comprised of two or more different abrasives having different sizes. In these embodiments, the total level of abrasive is preferably less than 5 wt. %.

The solvent which provides the principle portion of the liquid component can be water or mixtures of water with other liquids that are miscible with water. Examples of other liquids are alcohols, such as methanol and ethanol. Advantageously the solvent is water.

The slurry composition used in the method of this invention can be acidic, neutral or alkaline, and has a pH ranging from 2 to 10. Preferably, the pH ranges from 2.0 to 10.0, preferably 3 to 9.5, more preferably 4 to 9.

The wide pH ranges provide the advantages highly tunable W: TEOS selectivity.

The presence of fluorine compounds in the slurry is not preferred as they attack the dielectrics. In a preferred embodiment, the polishing composition is free of fluoride compounds.

Some CMP patents describe a polyamine azole as a component in CMP slurry(s). It is emphasized here that a polyamine azole is not a polyethyleneimine.

Stabilizers may also be used. At low pH, Stabilizers are optional. Stabilizers include but are not limited to organic carboxylic acids or organic carboxylic acid salts. These stabilizers include, but not limited to, citric acid, tartaric acid, lactic acid, oxalic acid, ascorbic acid, acetic acid, gluconic acid, and their sodium salts, potassium salts and ammonium salts.

Stabilizers can be used in the range of 250 ppm to 10000 ppm, and more preferred range of 400 ppm to 5000 ppm (or 0.04 wt. % to 0.5 wt. %).

The method of this invention entails use of the afore mentioned CMP compositions (as disclosed supra) for chemical mechanical planarization of substrates comprised of tungsten, barrier such as TiN or Ti, TaN or Ta; and dielectric materials such as TEOS, PETOES and low-k materials.

The method of chemical mechanical polishing a semiconductor substrate containing a surface comprising tungsten and at least one of dielectric layer or barrier layer, comprising steps of:
providing the semiconductor substrate;
providing a polishing pad;
providing the chemical mechanical polishing (CMP) compositions disclosed above contacting the surface of the semiconductor substrate with the polishing pad and the chemical mechanical polishing composition; and
polishing the surface of the semiconductor;
wherein
the dielectric layer is an oxide film and the barrier layer is selected from the group consisting of TiN, Ti, TaN, Ta and combinations thereof.

The removal selectivity of W vs the at least one dielectric layer or barrier layer is between 4:1 and 50 to 1.

The removal rate for tungsten is greater than 1300, 1500, 2000 Å/min, or 2500 Å/min; removal rate for the dielectric layer is between 15 to 200 Å/min; removal rate for the barrier layer is between 30 to 500 Å/min.

In one embodiment, the method comprises movably contacting a surface having tungsten thereon with a) an abrasive suspended in a liquid to form a slurry, said slurry comprising: between 0.1 and 20% by weight, for example between 0.5 and 5% by weight of said abrasive; said liquid comprising water; an acid or a base sufficient to provide a pH of 2 to 10; of a per-oxy oxidizer ranges from 1 ppm and 100000 ppm, preferably between 100 ppm to 50000 ppm, and more preferably between 5000 ppm to 35000 ppm by weight; and between 0.01 to 1000 ppm, preferably between 0.1 to 100 ppm, and more preferably between 0.5 to 10 ppm by weight; and most preferably between 1 to 5 ppm by weight of a polyethyleneimine; said liquid being substantially free of fluoride-containing compounds, wherein the polishing removes greater than 2000 angstroms per minute (Å/min) of tungsten and varied thickness of oxide films.

In another embodiment, the method comprises movably contacting a surface having tungsten thereon with a) an abrasive comprising silica, and b) a liquid component comprising water, an acid sufficient to provide a pH of 2 to 10, a per-oxy oxidizer, and between 0.1 and 10 ppm by weight of a polyethyleneimine, and between 0.1 and 4 ppm by weight of polyethyleneimine, wherein the polishing removes greater than 2000 angstroms per minute of tungsten and varied thickness of oxide films.

In yet another embodiment, the method comprises: movably contacting a surface of the substrate with a) an abrasive, and b) a liquid component comprising water, an acid sufficient to provide a pH of 2 to 10, a per-oxy oxidizer, between 50 ppm and 250 ppm by weight of an iron-ligand complex which reacts at elevated temperature induces the formation of hydroxyl radicals from with the per-oxy oxidizer to enhance W film oxidation reaction rate and tune tungsten removal rates, and between 0.1 and 10 ppm by weight of a polyethyleneimine.

Use of greater amounts of polyethyleneimine results in reduced tungsten removal rates while there is added static etch corrosion protection.

And in a preferred embodiment the polishing composition is free of fluoride-containing compounds.

In the method, a substrate (e.g., a wafer) is placed face-down toward a polishing pad which is fixedly attached to a rotatable platen of a CMP polisher. In this manner, the substrate to be polished and planarized is placed in direct contact with the polishing pad. A wafer carrier system or polishing head is used to hold the substrate in place and to apply a downward pressure against the backside of the substrate during CMP processing while the platen and the substrate are rotated. The polishing composition (slurry) is applied (usually continuously) on the pad during CMP processing to affect the removal of material to planarize the substrate.

In the method of the invention with use of the associated slurry, a removal rate of tungsten of at least greater than 1000 Angstroms per minute and a removal rate of TEOS is ranging from less than 10 Angstroms per minute to greater than 500 Angstroms per minute which are maintained upon chemical-mechanical polishing thereof when polishing is done at 3 psi or 4 psi of down force. Higher removal rates are obtained when down force values are increased.

As indicated above, an embodiment of the invention is a composition for chemical mechanical polishing a tungsten-containing substrate. In an embodiment, the surface of the substrate also has at least one feature thereon comprising a dielectric material, at least near the conclusion of the polishing. In an embodiment, the dielectric material is a silicon oxide.

The removal selectivity of tungsten over dielectric are between 5 and 500, which depend on the pH conditions of the invented W CMP polishing compositions herein.

The system of this invention entails use of the afore mentioned CMP compositions (as disclosed supra) for chemical mechanical planarization of substrates comprised of tungsten, barrier such as TiN or Ti, TaN or Ta; and dielectric materials such as TEOS, PETOES and low-k materials.

In yet another aspect, the invention is a system of chemical mechanical polishing of a substrate containing a surface comprising tungsten and at least one of dielectric layer such as oxide; and barrier films, such as TiN or Ti or TaN or Ta.

The system comprising:
a substrate containing a surface comprising tungsten and at least one of dielectric layer such as oxide; and barrier films, such as TiN or Ti or TaN or Ta;
a polishing pad;
the chemical mechanical polishing (CMP) compositions disclosed above;
wherein the surface of the semiconductor substrate is in contact with the polishing pad and the chemical mechanical polishing composition.

In each of the above embodiments, the term “ppm” means parts per million by weight of the slurry (liquid plus abrasive), or of the liquid component if there is no abrasive suspended in the liquid.

A growing trend among CMP slurry providers is the lowering of their customers' cost of consumables through product concentration. The practice of providing concentrated slurry is becoming a demand across the CMP industry. The level of concentration, however, must be prudently chosen so as not to jeopardize the stability and shelf-life time of the product.

Preferred slurries of the present invention include silica of a first (smaller) size and silica with a second (larger) size. Most preferred is an embodiment also including a third abrasive of an intermediate size. Because of having iron-ligand complex as catalyst, certain compounds can also be used in the slurries as extra ligands to provide more stable slurries, other suitable chemical components for W corrosion inhibition, such as PEI and other oligomers or polymers of ethyleneimine or propylenimine for film removal rates and selectivity tuning. Any organic corrosion inhibitor present must therefore be effective in an amount of a few ppm or less by weight. Polyethyleneimine, especially branched polyethyleneimine, is a preferred corrosion inhibitor.

We have found that even with slurry concentrates that minimize organics, which can exacerbate long term aging effects, slurry concentrates exhibit some effects on aging, especially relating to dishing and to absolute tungsten removal rates. Note that slurry concentrates are free of oxidizers, which are added when the slurry concentrate is tank mixed with water and oxidizer to form a polishing slurry. It is known to tune slurries by adding various components thereto. The invention here is a method of mixing two different slurry concentrates (called for convenience a primary slurry concentrates and a secondary slurry concentrate), wherein the ratio of mixing of the slurry concentrates depends on the long-term age of the primary slurry concentrate, to normalize slurry performance against aging.

### Glossary

### CMP Methodology

In the examples presented below, CMP experiments were run using the procedures and experimental conditions given below.

All percentages are weight percentages unless otherwise indicated.

### Components

Colloidal Silica: first colloidal silica used as abrasive having a mean particle size of approximately 45 nanometers (nm); second colloidal silica used as abrasive having a mean particle size of approximately 70 nanometers (nm);

Col Sil: Colloidal silica particles (with varied sizes) supplied by JGC Inc. in Japan or Fuso Chemical Inc. in Japan.

Ethyleneimine Oligomer Mixture Polyethyleneimine with a minor amount of tetraethylenepentamine (>=5% and <=20% from MSDS of this product) were supplied by Sigma-Aldrich, St. Louis, Mo.

PEI: Polyethyleneimine (Aldrich, Milwaukee, Wis.) Iron-Gluconate were upplied by Sigma-Aldrich

Iron-Oxalate Supplied by Sigma-Aldrich

Glaucomic acid was supplied by Sigma-Aldrich

TEOS: tetraethylorthosilicate

Polishing Pad: IC1000 and IC1010 were used during CMP, supplied by DOW, Inc.

### Parameters

### General

Å or A: angstrom(s)—a unit of length
BP: back pressure, in psi units
CMP: chemical mechanical planarization=chemical mechanical polishing
CS: carrier speed
DF: Down force: pressure applied during CMP, units psi
min: minute(s)
ml: milliliter(s)
mV: millivolt(s)
psi: pounds per square inch
PS: platen rotational speed of polishing tool, in rpm (revolution(s) per minute)
SF: slurry flow, ml/min
Wt. %: weight percentage (of a listed component)
TEOS: W Selectivity: (removal rate of TEOS)/(removal rate of W)

Tungsten Removal Rates: Measured tungsten removal rate at a given down pressure. The down pressure of the CMP tool was 4.0 psi in the examples listed above.

TEOS Removal Rates: Measured TEOS removal rate at a given down pressure. The down pressure of the CMP tool was 4.0 psi in the examples listed above.

TiN Removal Rates: Measured TEOS removal rate at a given down pressure. The down pressure of the CMP tool was 4.0 psi in the examples listed above.

Tungsten films were measured with a ResMap CDE, model 168, manufactured by Creative Design Engineering, Inc, 20565 Alves Dr., Cupertino, Calif., 95014. The ResMap tool is a four-point probe sheet resistance tool. Forty-nine-point diameter scan at 5 mm edge exclusion for Tungsten film was taken.

### CMP Tool

The CMP tool that was used is a 200 mm Mirra, manufactured by Applied Materials, 3050 Boweres Avenue, Santa Clara, Calif., 95054. An IC1000 pad supplied by DOW, Inc, 451 Bellevue Rd., Newark, Del. 19713 was used on platen 1 for blanket and pattern wafer studies.

The IC1000 or IC1010 pad was broken in by conditioning the pad for 18 mins. At 7 Ibs down force on the conditioner. To qualify the tool settings and the pad break-in two tungsten monitors and two TEOS monitors were polished with Versum® W5900, supplied by Versum Materials Inc. at baseline conditions.

### WORKING EXAMPLES

The present invention is further demonstrated by the examples below.

Polishing experiments were conducted using CVD deposited Tungsten wafers and PECVD TEOS wafers. These blanket wafers were purchased from Silicon Valley Microelectronics, 2985 Kifer Rd., Santa Clara, Calif. 95051. The film thickness specifications are summarized below: W: 8,000 Å CVD tungsten, 240 Å TiN, 5000 Å TEOS on silicon.

### Polishing Experiments

In blanket wafer studies, tungsten blanket wafers, TiN blanket wafers and TEOS blanket wafers were polished at baseline conditions. The tool baseline conditions were: table speed; 120 rpm, head speed: 123 rpm, membrane pressure; 4.0 psi, inter-tube pressure; 6.0 psi, retaining ring pressure; 6.5 psi, slurry flow; 120 ml/min.

The slurry was used in polishing experiments on patterned wafers (SKW754 or SWK854), supplied by SWK Associates, Inc. 2920 Scott Blvd. Santa Clara, Calif. 95054). These wafers were measured on the Veeco VX300 profiler/AFM instrument.

The 5 different sized line structure were used for dishing measurement, and 5 different micron array were used for the erosion measurement. The wafer was measured at center, middle, and edge die positions.

The W CMP buffering polishing compositions also provided d tunable TEOS film removal rates, high and tunable barrier film, such as TiN film, removal rates, and tunable W film removal rates.

W: TEOS Selectivity: (removal rate of W)/(removal rate of TEOS) obtained from the W CMP polishing compositions were tunable and ranged from 5:1 to 50:1.

### Example 1

In the composition, 45 nm sized colloidal silica at 0.0945 wt. % was used as first abrasive, and 70 nm sized colloidal silica at 0.125 wt. % was used as second abrasive, iron-gluconate hydrate at 0.0125% wt. % was used as iron-ligand complex catalyst, gluconic acid at 0.075 wt. % was used as another additive, and 3.0 wt. % H₂O₂ was used as oxidizing agent. The composition had pH value at 7.7. A biocide was used at 0.0025 wt. % for preventing the formation and growing of bacteria around neutral pH.

The polishing results at 4.0 psi DF yielded the following film removal rates: W RR (Å/min.) was 4198 Å/min., TiN RR was 1017 Å/min., and TEOS RR was 25 Å/min.

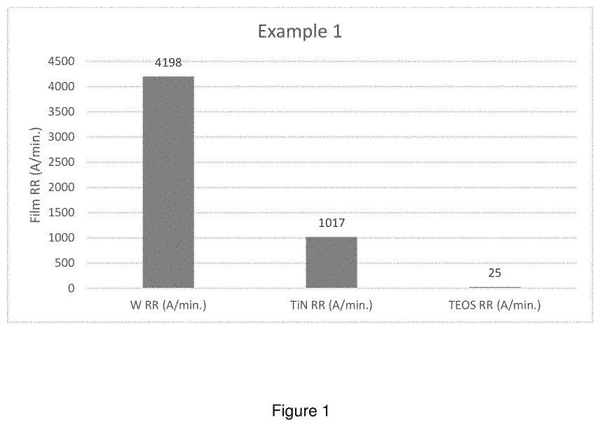

The results were depicted in FIG. 1. The selectivity of W: TEOS was about 164:1 which represents a highly selective W CMP bulk polishing composition.

The W line dishing and erosion results were listed in Table 1.

TABLE 1
W Line Dishing and Erosion of Example 1 W CMP Polish Composition

| Example 1 | 2 × 2 μm | 5 × 5 μm | 10 × 10 μm | 7 × 3 μm | 9 × 1 μm |
|---|---|---|---|---|---|
| W Line | 463 | 786 | 1052 | 805 | 656 |
| Dishing | | | | | |
| Erosion | 255 | 167 | 34 | 335 | 778 |

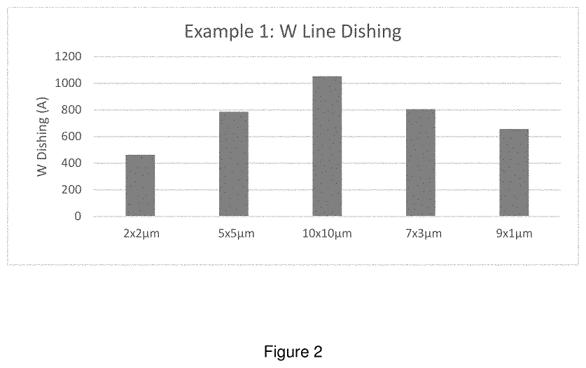

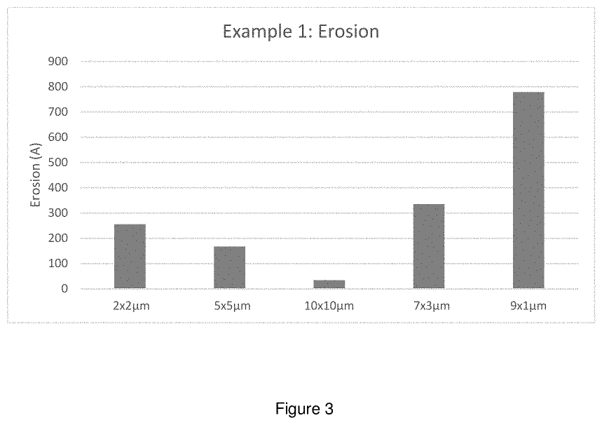

The W line dishing and erosion results were also depicted in FIG. 2 and FIG. 3.

The W line dishing and erosion data showed in Table 1 can be described as low W line dishing and erosion.

There are reported W dishing and erosion data on other W CMP polishing compositions which typically have W line dishing >1500 A on wide line features, and have erosion on high density features such as 70% and 90% density >1000 A.

### Example 2

In Example 2, 0.0125 wt. % of iron-gluconate was used as iron-ligand complex catalyst, 0.0945 wt. % of a 45 nm colloidal silica was used at first abrasive, 1.0 wt. % of a high purity colloidal silica (with mean particle size at 70 nm) was used as second abrasive, Lupasol (a PEI molecule) was used as corrosion inhibitor at 0.0003 wt. %, pH was adjust to 2.5 using inorganic acid, and 1.0 wt. % H₂O₂ was used as oxidizing agent.

The polishing was conducted under 4.0 psi down force.

The polishing results at 4.0 psi Down Force yielded the following film removal rates: W RR (A/min.) was 3305 A/min., TiN RR was 1430 A/min., and TEOS RR was 653 A/min.

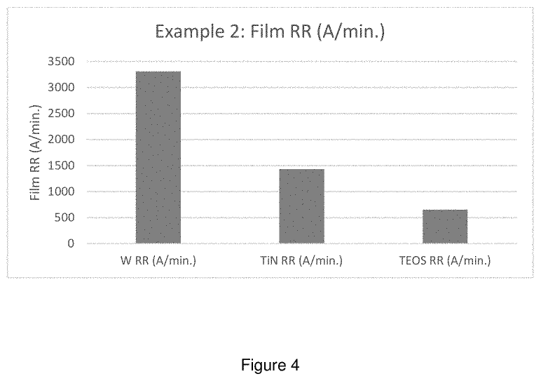

The results were also depicted in FIG. 4. The selectivity of W: TEOS was about 5.1:1 which represents a highly selective W CMP bulk polishing composition.

The W line dishing and erosion results were listed in Table 2.

TABLE 2
W Line Dishing and Erosion of Example 2 W CMP Polish Composition

| Example 2 | 2 × 2 μm | 5 × 5 μm | 10 × 10 μm | 7 × 3 μm | 9 × 1 μm |
|---|---|---|---|---|---|
| W Line | 193 | 302 | 468 | 270 | 222 |
| Dishing | | | | | |

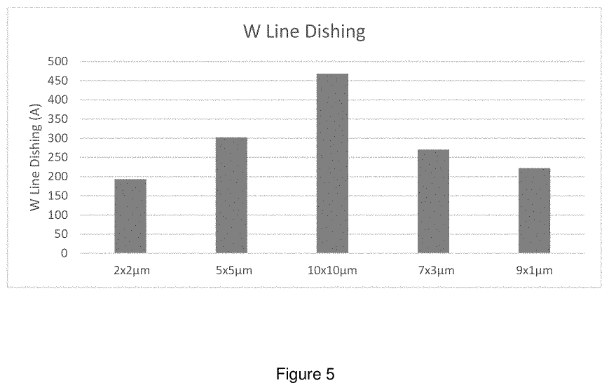

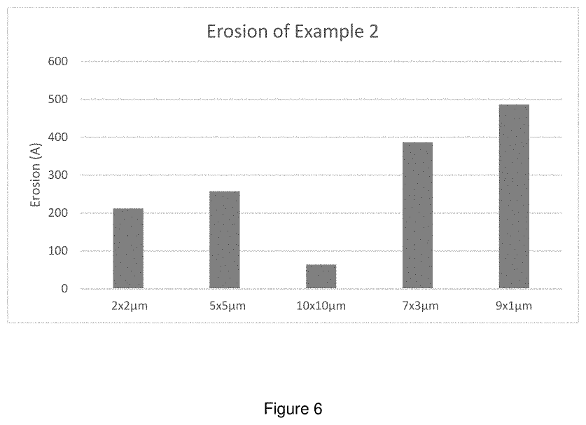

The W line dishing and erosion results were also depicted in FIG. 5 and FIG. 6.

As showing in Example 1 and Example 2, CMP polishing compositions using iron-ligand complex as catalyst can be used in wide pH ranges which allow the easy tuning of W: TEOS selectivity, such as W:TEOS selectivity at pH 7.7 is 164:1 vs a selectivity about 5:1 at pH 2.5

### Example 3

In Example 3, 0.0125 wt. % of iron(III)-oxalate was used as iron-ligand complex catalyst, 0.0945 wt. % of 45 nm colloidal silica was used at first abrasive, 1.0 wt. % of a high purity colloidal silica (with mean particle size at 70 nm) was used as second abrasive, Lupasol (a PEI molecule) was used as corrosion inhibitor at 0.0003 wt. %, pH was adjust to 2.5 using inorganic acid, and 1.0 wt. % H₂O₂ was used as oxidizing agent.

The polishing was conducted under 4.0 psi down force.

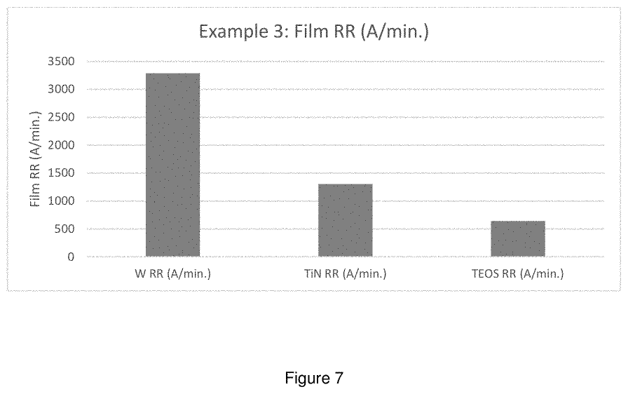

The film removal rates were depicted in FIG. 7.

W line dishing and erosion results are listed in Table 3.

TABLE 3
W Line Dishing and Erosion of Example 3 W CMP Polish Composition

| Example 3 | 2 × 2 μm | 5 × 5 μm | 10 × 10 μm | 7 × 3 μm | 9 × 1 μm |
|---|---|---|---|---|---|
| W Line | 189 | 284 | 440 | 269 | 211 |
| Dishing | | | | | |
| Erosion | 146 | 177 | 21 | 423 | 437 |

The polishing results at 4.0 psi down force yielded the following film removal rates for Example 3: W RR (A/min.) was 3286 A/min., TiN RR was 1305 A/min., and TEOS RR was 642 A/min. The selectivity of W: TEOS was about 5.1:1 which represents a low selective W CMP bulk polishing composition.

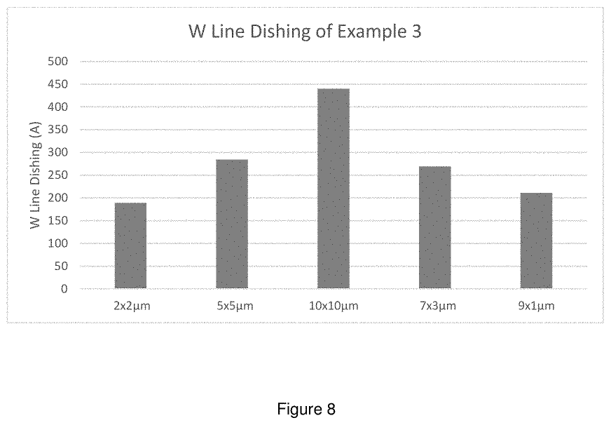

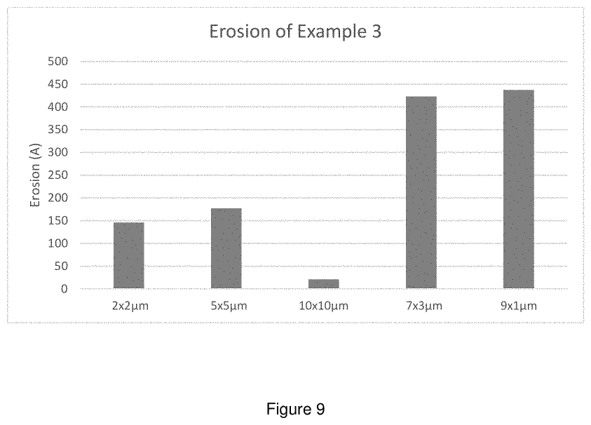

The W line dishing and erosion results were depicted in FIG. 8 and FIG. 9.

The slurry composition of Examples 1, 2 and 3 were prepared with the addition of 1.0 wt. % H₂O₂ at least 30 minutes prior to polishing tests. Dishing and erosion data was obtained using such samples after completing polishing on blanket wafers and W patterned wafers.

### Example 4

In this example, the compositions comprised 45 nm sized (spherical shape) colloidal silica at 0.0945 wt. % as first abrasive, and 70 nm sized (cocoon shape) high purity colloidal silica at 0.125 wt. % as second abrasive, iron-gluconate hydrate at 0.0125% wt. % (Examples 1 to 4) or ammonium iron-oxalate trihydrate (Examples 5 to 6) as iron-ligand complex catalyst, gluconic acid at 0.075 wt. %, and 1.0 wt. % H₂O₂ as oxidizing agent. The composition had pH value at 7.0. A biocide was used at 0.0025 wt. % for preventing the formation and growing of bacteria around neutral pH.

Also in the compositions 7 and 8, 45 nm sized colloidal silica at 0.0945 wt. % was used as first abrasive, and 70 nm sized colloidal silica at 0.125 wt. % was used as second abrasive, ferric nitrate monohydrate at 0.01 wt. % was used as water-soluble ferric inorganic salt as catalyst at pH 5.5 or pH 7.0, malonic acid was used at 0.05 wt. %, and 1.0 wt. % H₂O₂ was used as oxidizing agent. The composition had pH value at 5.5 and 7.0. A biocide was used at 0.0025 wt. % for preventing the formation and growing of bacteria around neutral pH.

The stability test results were listed in Table 4.

TABLE 4
W CMP Polishing Composition Stability Test Results vs pH

| Compositions | Sample 1 | Sample 2 | Sample 3 | Sample 4 | Sample 5 | Sample 6 | Sample 7 | Sample 8 |
|---|---|---|---|---|---|---|---|---|
| iron gluconate catalyst | 0.0125 | 0.0125 | 0.0125 | 0.0125 | | | | |
| Gluconic acid | | | 0.0500 | 0.0500 | | | | |
| 45 nm Colloidal Silica | 0.0945 | 0.0945 | 0.0945 | 0.0945 | 0.0945 | 0.0945 | 0.0945 | 0.0945 |
| Ammonium iron oxlate | | | | | 0.01250 | 0.01250 | | |
| catalyst | | | | | | | | |
| Oxalic Acid | | | | | 0.05 | 0.05 | | |
| Corrosion Inhibitor | | 0.00033 | | 0.00033 | | 0.00033 | | |
| ferric nitrate monohydrate | | | | | | | 0.01 | 0.01 |
| catalyst | | | | | | | | |
| malonic acid | | | | | 0.05 | 0.05 | 0.05 | 0.05 |
| 70 nm Colloidal Silica | 1.0 | 1.0 | 1.0 | 1.0 | 1.0 | 1.0 | 1.0 | 1.0 |
| pH | 7.0 | 7.0 | 7.0 | 7.0 | 7.0 | 7.0 | 5.5 | 7.0 |
| H2O2 | 1 | 1 | 1 | 1 | 1 | 1 | 1 | 1 |
| Stability | Stable | Stable | Stable | Stable | Stable | Stable | Unstable, | Unstable, |
| | | | | | | | particles | particles |
| | | | | | | | crashed out | crashed out |

As the W polishing composition stability test results shown in Table 4, stable compositions were obtained when two water-soluble iron-ligand complexes, iron-gluconate and ammonium iron-oxalate were used at catalysts at neutral pH conditions, regardless the presence or absence of additional ligand molecules, gluconic acid or oxalic acid molecules, and W corrosion inhibitor.

But when ferric nitrate compound was used as catalyst in the compositions, the used colloidal silica abrasives went through gelation processes quickly, and all colloidal silica particles were crashed out either at pH 5.5 or pH 7.0.

The afore polishing composition stability tests at selected pH conditions shown that iron-ligand compounds can be used as catalysts in W CMP slurries in more broader pH ranges, specifically ≥5.5; while water-soluble inorganic salts of iron, such as ferric nitrate will not give a stable polishing composition at the pH range.

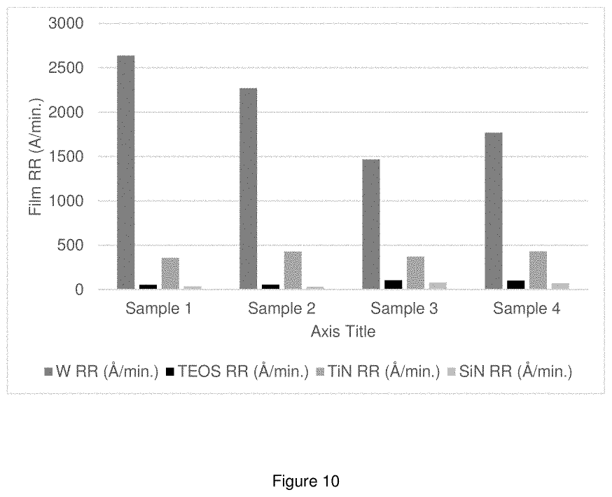

Film removal rates for W, TEOS, TiN and SiN using Examples 1 to 4 were shown in Table 5 and depicted in FIG. 10.

TABLE 5
W Polishing Compositions and Film Removal Rates (Å/min.)

| Compositions | Sample 1 | Sample 2 | Sample 3 | Sample 4 |
|---|---|---|---|---|
| iron gluconate | 0.0125 | 0.0125 | 0.0125 | 0.0125 |
| catalyst | | | | |
| Gluconic acid | | | 0.0500 | 0.0500 |
| 45 nm Colloidal | 0.0945 | 0.0945 | 0.0945 | 0.0945 |
| Silica | | | | |
| Corrosion Inhibitor | | 0.00033 | | 0.00033 |
| 70 nm Colloidal | 1.0 | 1.0 | 1.0 | 1.0 |
| Silica | | | | |
| pH | 7.0 | 7.0 | 7.0 | 7.0 |
| H2O2 | 1 | 1 | 1 | 1 |
| W RR (Å/min.) | 2637 | 2269 | 1466 | 1768 |
| TEOS RR (Å/min.) | 53 | 55 | 104 | 101 |
| TiN RR (Å/min.) | 358 | 429 | 371 | 431 |
| SiN RR (Å/min.) | 35 | 32 | 79 | 72 |

The results from Examples 1 and 2 as shown in Table 5 and FIG. 10 showed that having W corrosion inhibitor but not having gluconic acid in the polishing composition (Example 2) suppressed W removal rate, boosted TiN removal rate, but had no impacts on TEOS and SiN film removal rate.

The results from Examples 1 and 3 as shown in Table 5 and FIG. 10 showed that the addition of ligand molecules of gluconic acid in the polishing composition but without adding W corrosion inhibitor suppressed W removal rate significantly, doubled TEOS and SiN removal rate, but almost had no impact on TiN removal rate.

Comparing with Example 1, when both ligand molecules of gluconic acid and W corrosion inhibitor were both used in the polishing composition as shown in Example 4, W removal rate was still being significantly reduced, TEOS and SiN removal rate were both doubled, and TiN removal rate was also increased.

The W patterned wafers were also being polished with 20% over polishing condition using the W CMP polishing compositions Examples 1 to 4 as in Table 6.

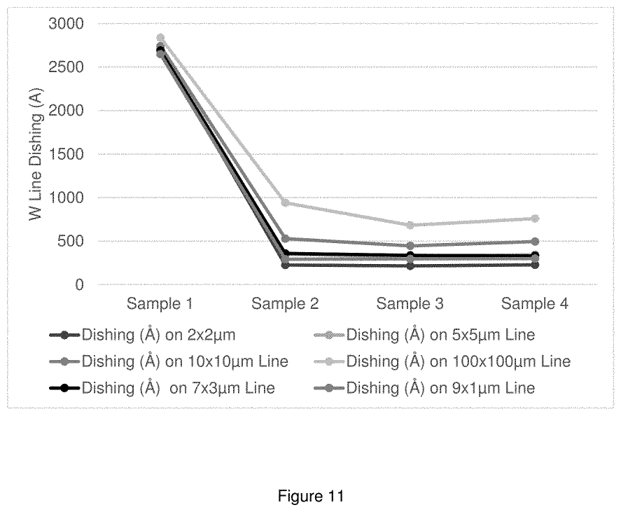

The effects of W CMP polishing compositions using (Examples 1 to 4) on various sized and density W lines were listed in Table 6 and depicted in FIG. 11.

TABLE 6
Effects of Different W CMP Compositions on W Line Dishing (Å)

| Compositions | Sample 1 | Sample 2 | Sample 3 | Sample 4 |
|---|---|---|---|---|
| iron gluconate catalyst | 0.0125 | 0.0125 | 0.0125 | 0.0125 |
| Gluconic acid | | | 0.0500 | 0.0500 |
| 45 nm Colloidal Silica | 0.0945 | 0.0945 | 0.0945 | 0.0945 |
| Corrosion Inhibitor | | 0.00033 | | 0.00033 |
| 70 nm Colloidal Silica | 1.0 | 1.0 | 1.0 | 1.0 |
| pH | 7.0 | 7.0 | 7.0 | 7.0 |
| H2O2 | 1 | 1 | 1 | 1 |
| Dishing (Å) on 2 × 2 μm | 2706 | 227 | 216 | 228 |
| Dishing (Å) on 5 × | 2719 | 351 | 321 | 345 |
| 5 μm Line | | | | |
| Dishing (Å) on 10 × | 2741 | 531 | 446 | 495 |
| 10 μm Line | | | | |
| Dishing (Å) on 100 × | 2837 | 941 | 683 | 760 |
| 100 μm Line | | | | |
| Dishing (Å) on 7 × 3 μm | 2689 | 359 | 336 | 332 |
| Line | | | | |
| Dishing (Å) on 9 × 1 μm | 2647 | 293 | 297 | 300 |
| Line | | | | |

As the W line dishing results shown in Table 6 and FIG. 11, Example 1 without using corrosion inhibitor or ligand molecule gluconic acid gave the W line dishing over 2680 Å (bad dishing). After adding the corrosion inhibitor alone into the polishing composition (Example 2), the various sized and density W line dishing were significantly reduced. While adding ligand molecules gluconic acid alone into the polishing composition (Example 3), W line dishing were also being reduced significantly. When using both corrosion inhibitor and ligand compound in the same W polishing composition (Example 4), W line dishing remained.

The embodiments of this invention listed above, including the working example, are exemplary of numerous embodiments that may be made of this invention. It is contemplated that numerous other configurations of the process may be used, and the materials used in the process may be elected from numerous materials other than those specifically disclosed.

1. A chemical-mechanical planarization (CMP) composition comprising:
abrasive selected from the group consisting of alumina, ceria, germania, colloidal silica, high purity colloidal silica having trace metal level <1 ppm, titania, zirconia particles, a metal-modified or composite particles, and combinations thereof; and the abrasive particles have a mean size ranging from 20 nm to 180 nm;
metal-ligand complex catalyst;
oxidizing agent; and
solvent selected from the group consisting of water, liquid which is miscible with water, and combinations thereof;
optionally,
corrosion inhibitor for W;
pH adjusting agent;
biocide; and
stabilizer;
wherein pH of the CMP composition ranges are from 4 to 9 and the CMP composition is a stable composition;
the metal-ligand complex catalyst has general molecular structure of:
M(n+)−Lm;
wherein
n+ refers the oxidation number of metal ions in metal-ligand complexes and n+ is 1+, 2+, 3+;
m refers to the numbers of the ligand molecules directly and chemical bonded to the cationic iron center in the metal-ligand complex and m is 1, 2, 3, 4, 5, or 6 respectively depending on ligand molecule in forming the metal-ligand complex;
the metal ions is selected from the group consisting of Fe, Cs, Ce, Ru, Os, Co, Rh, Ir, Ni, Pd, Pt, Cu, Ag, Au ions; and
ligand molecule L is selected from the group consisting of organic acids with mono-, bi-, tri-, or tetra-carboxylic; sulfonic or phosphoric acid functional groups; ammonium salt, potassium salt or sodium salt with mono-, bi-, tri-, tetra-carbonate, sulfonate or phosphate functional groups; pyridine molecule and its derivatives; bipyridine molecule and its derivatives; terpyridine and its derivatives; picolinic acid and its derivatives; and combinations thereof.

2. The chemical-mechanical planarization (CMP) composition of claim 1, wherein the metal-ligand complex catalyst is an iron-ligand complex catalyst selected from the group comprising 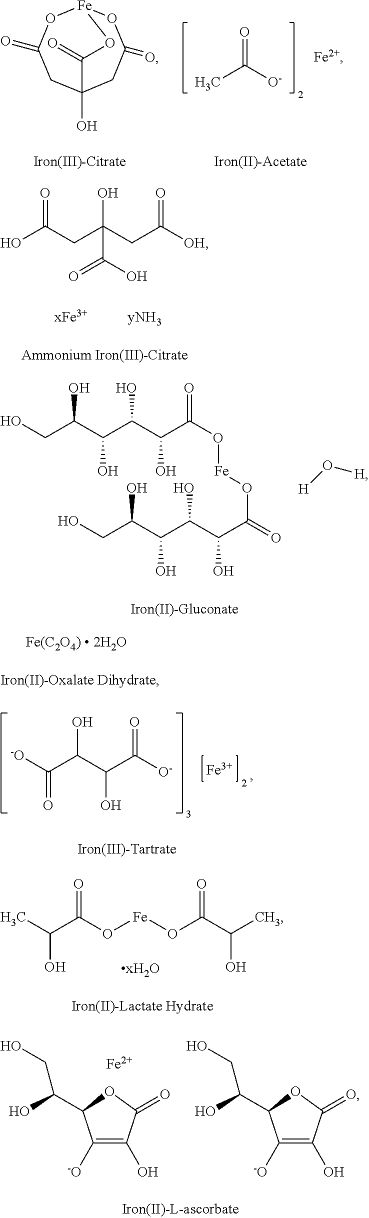
and combinations thereof.

3. The chemical-mechanical planarization (CMP) composition of claim 1, wherein the corrosion inhibitor for W ranges between 0.5 to 10 ppm and is selected from the group consisting of an oligomer or polymer comprising ethyleneimine, polyethyleneimine(PEI), propyleneimine, and combinations thereof;
wherein the polyethyleneimine (PEI) can be either branched or linear; at least half of the branched polyethyleneimines are branched and contain primary, secondary and tertiary amino groups; and the linear polyethyleneimines contain secondary amines.

4. The chemical-mechanical planarization (CMP) composition of claim 3, wherein the branched polyethyleneimine can be represented by the formula (—NHCH₂CH₂—)ₓ[—N(CH₂CH₂NH₂)CH₂CH₂—]_{y} shown below: 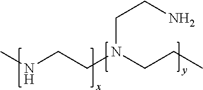
wherein x and y each can be independently 2 to 40; alternately, each of x and y are independently 6 to 10.

5. The chemical-mechanical planarization (CMP) composition of claim 1, wherein
the oxidizing agent is selected from the group consisting of per-oxy oxidizer comprising at least one peroxy group (—O—O—); H₂O₂ and urea hydrogen peroxide; sodium or potassium peroxide; benzyl peroxide; di-t-butyl peroxide; persulfates comprising monopersulfates or dipersulfates, percarbonates, perchlorates, perbromates, periodates, and acids thereof; peroxyacids comprising peracetic acid, perbenzoic acid, m-chloroperbenzoic acid, and salts thereof; iodic acid and salts thereof; nitric acid; and combinations thereof; and the oxidizing agent ranges from 1 ppm and 100000 ppm;
the biocides comprise active ingredients of 5-chloro-2-methyl-4-isothiazolin-3-one and 2-methyl-4-isothiazolin-3-one;
the pH adjusting agent is selected from the group consisting of (1) inorganic acid selected from the group consisting of nitric acid, sulfonic acid, phosphoric acid and combinations thereof; (2) inorganic base selected from the group consisting of ammonia hydroxide, potassium hydroxide, sodium hydroxide and combinations thereof; and
the stabilizer selected from the group consisting of citric acid, tartaric acid, lactic acid, oxalic acid, ascorbic acid, acetic acid, gluconic acid, and their sodium salts, potassium salts, ammonium salts; and combinations thereof.

6. The chemical-mechanical planarization (CMP) composition of claim 1, wherein the composition comprises iron-gluconate hydrate or iron(III)-oxalate; colloidal silica, high purity colloidal silica with <1 ppm trace metal, and combinations thereof; wherein the abrasive has size ranging 30 nm to 150 nm; iron-gluconate hydrate or ammonium iron-oxalate trihydrate; H₂O₂; polyethyleneimine(PEI); water; and optionally gluconic acid; and biocide.

7. A method of chemical mechanical polishing a semiconductor substrate containing a surface comprising tungsten and at least one of dielectric layer or barrier layer, comprising steps of:
providing the semiconductor substrate;
providing a polishing pad;
providing the chemical mechanical polishing (CMP) composition comprising
abrasive selected from the group consisting of alumina, ceria, germania, colloidal silica, high purity colloidal silica having trace metal level <1 ppm, titania, zirconia particles, a metal-modified or composite particles, and combinations thereof; and the abrasive particles have a mean size ranging from 20 nm to 180 nm;
metal-ligand complex catalyst;
oxidizing agent; and
solvent selected from the group consisting of water, liquid which is miscible with water, and combinations thereof;
optionally,
corrosion inhibitor for W;
pH adjusting agent;
biocide; and
stabilizer;
wherein pH of the CMP composition ranges are from 4 to 9 and the CMP composition is a stable composition;
wherein the metal-ligand complex catalyst has general molecular structure of:
M(n+)−Lm;
wherein
n+ refers the oxidation number of metal ions in metal-ligand complexes and n+ is 1+, 2+, 3+;
m refers to the numbers of the ligand molecules directly and chemical bonded to the cationic iron center in the metal-ligand complex and m is 1, 2, 3, 4, 5, or 6 respectively depending on ligand molecule in forming the metal-ligand complex;
the metal ions is selected from the group consisting of Fe, Cs, Ce, Ru, Os, Co, Rh, Ir, Ni, Pd, Pt, Cu, Ag, Au ions; and
ligand molecule L is selected from the group consisting of organic acids with mono-, bi-, tri-, or tetra-carboxylic; sulfonic or phosphoric acid functional groups; ammonium salt, potassium salt or sodium salt with mono-, bi-, tri-, tetra-carbonate, sulfonate or phosphate functional groups; pyridine molecule and its derivatives; bipyridine molecule and its derivatives; terpyridine and its derivatives; picolinic acid and its derivatives; and combinations thereof;
contacting the surface of the semiconductor substrate with the polishing pad and the chemical mechanical polishing composition; and
polishing the surface of the semiconductor;
wherein
the dielectric layer is an oxide film and the barrier layer is selected from the group consisting of TiN, Ti, TaN, Ta and combinations thereof.

8. The method of claim 7, wherein the dielectric layer is a silicon oxide film (TEOS) and the barrier layer is TiN, and removal selectivity of W vs TEOS or TiN is between 4:1 or 50 to 1.

9. The method of claim 7, wherein the metal-ligand complex catalyst is an iron-ligand complex catalyst selected from the group comprising 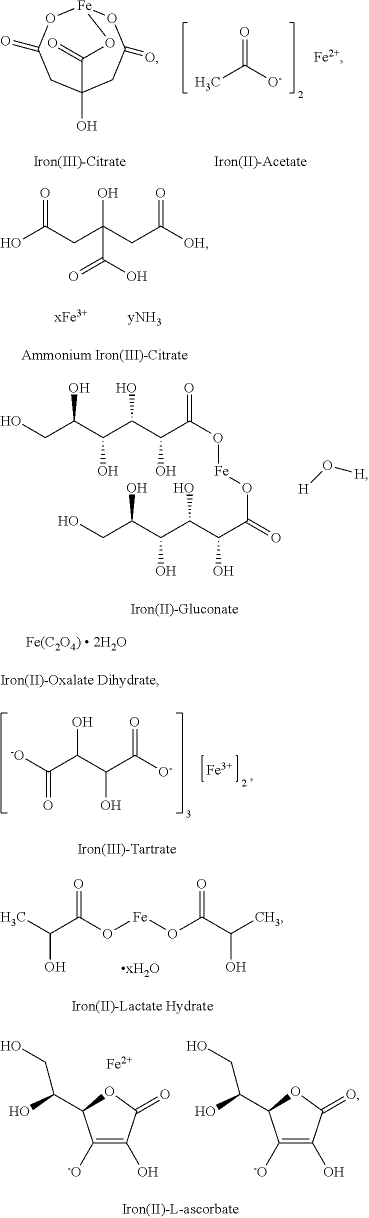
and combinations thereof.

10. The method of claim 7, wherein the corrosion inhibitor for W ranges between 0.5 to 10 ppm and is selected from the group consisting of an oligomer or polymer comprising ethyleneimine, polyethyleneimine(PEI), propyleneimine, and combinations thereof;
wherein the polyethyleneimine (PEI) can be either branched or linear; at least half of the branched polyethyleneimines are branched and contain primary, secondary and tertiary amino groups; and the linear polyethyleneimines contain secondary amines.

11. The method of claim 10, wherein the branched polyethyleneimine can be represented by the formula (—NHCH₂CH₂—)ₓ[—N(CH₂CH₂NH₂)CH₂CH₂—]_{y} shown below: 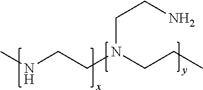
wherein x and y each can be independently 2 to 40; alternately, each of x and y are independently 6 to 10.

12. The method of claim 7, wherein
the oxidizing agent is selected from the group consisting of per-oxy oxidizer comprising at least one peroxy group (—O—O—); H₂O₂ and urea hydrogen peroxide; sodium or potassium peroxide; benzyl peroxide; di-t-butyl peroxide; persulfates comprising monopersulfates or dipersulfates, percarbonates, perchlorates, perbromates, periodates, and acids thereof; peroxyacids comprising peracetic acid, perbenzoic acid, m-chloroperbenzoic acid, and salts thereof; iodic acid and salts thereof; nitric acid; and combinations thereof; and the oxidizing agent ranges from 1 ppm and 100000 ppm;
the biocides comprise active ingredients of 5-chloro-2-methyl-4-isothiazolin-3-one and 2-methyl-4-isothiazolin-3-one;
the pH adjusting agent is selected from the group consisting of (1) inorganic acid selected from the group consisting of nitric acid, sulfonic acid, phosphoric acid and combinations thereof; (2) inorganic base selected from the group consisting of ammonia hydroxide, potassium hydroxide, sodium hydroxide and combinations thereof; and
the stabilizer selected from the group consisting of citric acid, tartaric acid, lactic acid, oxalic acid, ascorbic acid, acetic acid, gluconic acid, and their sodium salts, potassium salts, ammonium salts; and combinations thereof.

13. The method of claim 7, wherein the composition comprises iron-gluconate hydrate or iron(III)-oxalate; colloidal silica, high purity colloidal silica with <1 ppm trace metal, and combinations thereof; wherein the abrasive has size ranging 30 nm to 150 nm; iron-gluconate hydrate or ammonium iron-oxalate trihydrate; H₂O₂; polyethyleneimine(PEI); water; and optionally gluconic acid; and biocide.

14. A system for chemical mechanical polishing a semiconductor substrate containing a surface comprising tungsten and at least one of dielectric layer or barrier layer, comprising:
the semiconductor substrate;
a polishing pad;
providing the chemical mechanical polishing (CMP) composition comprising
abrasive selected from the group consisting of alumina, ceria, germania, colloidal silica, high purity colloidal silica having trace metal level <1 ppm, titania, zirconia particles, a metal-modified or composite particles, and combinations thereof; and the abrasive particles have a mean size ranging from 20 nm to 180 nm;
metal-ligand complex catalyst;
oxidizing agent; and
solvent selected from the group consisting of water, liquid which is miscible with water, and combinations thereof;
optionally,
corrosion inhibitor for W;
pH adjusting agent;
biocide; and
stabilizer;
wherein pH of the CMP composition ranges are from 4 to 9 and the CMP composition is a stable composition;
wherein the metal-ligand complex catalyst has general molecular structure of:
M(n+)−Lm;
wherein
n+ refers the oxidation number of metal ions in metal-ligand complexes and n+ is 1+, 2+, 3+;
m refers to the numbers of the ligand molecules directly and chemical bonded to the cationic iron center in the metal-ligand complex and m is 1, 2, 3, 4, 5, or 6 respectively depending on ligand molecule in forming the metal-ligand complex;
the metal ions is selected from the group consisting of Fe, Cs, Ce, Ru, Os, Co, Rh, Ir, Ni, Pd, Pt, Cu, Ag, Au ions; and
ligand molecule L is selected from the group consisting of organic acids with mono-, bi-, tri-, or tetra-carboxylic; sulfonic or phosphoric acid functional groups; ammonium salt, potassium salt or sodium salt with mono-, bi-, tri-, tetra-carbonate, sulfonate or phosphate functional groups; pyridine molecule and its derivatives; bipyridine molecule and its derivatives; terpyridine and its derivatives; picolinic acid and its derivatives; and combinations thereof;
wherein the surface of the semiconductor substrate is in contact with the polishing pad and the chemical mechanical polishing composition.

15. The system of claim 14, wherein the dielectric layer is a silicon oxide film (TEOS) and the barrier layer is TiN, and removal selectivity of W vs TEOS or TiN is between 4:1 or 50 to 1.

16. The system of claim 14, wherein the metal-ligand complex catalyst is an iron-ligand complex catalyst selected from the group comprising 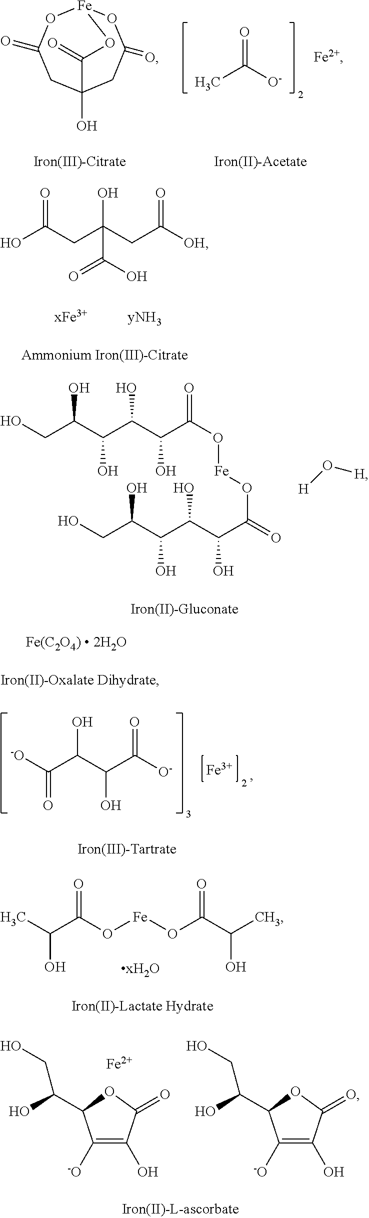
and combinations thereof.

17. The system of claim 14, wherein the corrosion inhibitor for W ranges between 0.5 to 10 ppm and is selected from the group consisting of an oligomer or polymer comprising ethyleneimine, polyethyleneimine(PEI), propyleneimine, and combinations thereof;
wherein the polyethyleneimine (PEI) can be either branched or linear; at least half of the branched polyethyleneimines are branched and contain primary, secondary and tertiary amino groups; and the linear polyethyleneimines contain secondary amines.

18. The system of claim 17, wherein the branched polyethyleneimine can be represented by the formula (—NHCH₂CH₂—)ₓ[—N(CH₂CH₂NH₂)CH₂CH₂—]_{y} shown below: 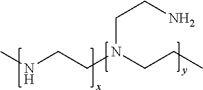
wherein x and y each can be independently 2 to 40; alternately, each of x and y are independently 6 to 10.

19. The system of claim 14, wherein
the oxidizing agent is selected from the group consisting of per-oxy oxidizer comprising at least one peroxy group (—O—O—); H₂O₂ and urea hydrogen peroxide; sodium or potassium peroxide; benzyl peroxide; di-t-butyl peroxide; persulfates comprising monopersulfates or dipersulfates, percarbonates, perchlorates, perbromates, periodates, and acids thereof; peroxyacids comprising peracetic acid, perbenzoic acid, m-chloroperbenzoic acid, and salts thereof; iodic acid and salts thereof; nitric acid; and combinations thereof; and the oxidizing agent ranges from 1 ppm and 100000 ppm;
the biocides comprise active ingredients of 5-chloro-2-methyl-4-isothiazolin-3-one and 2-methyl-4-isothiazolin-3-one;
the pH adjusting agent is selected from the group consisting of (1) inorganic acid selected from the group consisting of nitric acid, sulfonic acid, phosphoric acid and combinations thereof; (2) inorganic base selected from the group consisting of ammonia hydroxide, potassium hydroxide, sodium hydroxide and combinations thereof; and
the stabilizer selected from the group consisting of citric acid, tartaric acid, lactic acid, oxalic acid, ascorbic acid, acetic acid, gluconic acid, and their sodium salts, potassium salts, ammonium salts; and combinations thereof.

20. The system of claim 14, wherein the composition comprises iron-gluconate hydrate or iron(III)-oxalate; colloidal silica, high purity colloidal silica with <1 ppm trace metal, and combinations thereof; wherein the abrasive has size ranging 30 nm to 150 nm; iron-gluconate hydrate or ammonium iron-oxalate trihydrate; H₂O₂; polyethyleneimine(PEI); water; and optionally gluconic acid; and biocide.
